(19) United States
(12) Patent Application Publication
(10) Pub. No.: US 2005/0206455 A1
(43) Pub. Date: Sep. 22, 2005

(54) Method to control the supply power being provided to a power amplifier

(76) Inventors: Ryo Yamazaki, Suwanee, GA (US); William Noellert, Atlanta, GA (US)

Correspondence Address: SMITH FROHWEIN TEMPEL GREENLEE BLAHA, LLC, P.O. BOX 88148, ATLANTA, GA, 30356, US

(21) Appl. No.: 10/803,756

(22) Filed: Mar. 18, 2004

(51) Int. Cl. H03G 3/10

(52) U.S. Cl. 330/285

(57) ABSTRACT

When a power amplifier operates near or in saturation, the quality of the output signal can be degraded and an over current condition can occur. To prevent this, the level of the power supply voltage being provided to the power amplifier must be monitored and controlled. One technique is to provide the supply power to the power amplifier through a pass transistor. By characterizing the resistance of the pass transistor and sensing the voltage drop across the pass transistor, the current being provided to the power amplifier can be determined. If this current is too high, the control input to the pass transistor can be adjusted to limit the current.

### CROSS-REFERENCE TO RELATED APPLICATIONS

This application is related to U.S. patent application Ser. No. ______ entitled “METHOD TO PREVENT SATURATION IN POWER AMPLIFIER CONTROL LOOP” filed on the same date at this application and commonly assigned to the assignee of this application, which application is incorporated herein by reference in its entirety.

### TECHNICAL FIELD

The present invention is directed towards radio frequency transmission technology and, more specifically, towards a technique to detect and prevent saturation in a power amplifier control loop of a transmitter and thereby, reduce spurious outputs caused by loop saturation and over current conditions.

### BACKGROUND

Cellular telephone technology has greatly advanced since its inception in the early 80's. Today, the Global System for Mobile communication (GSM) is one of the more prominent technologies being deployed in cellular systems throughout the world. GSM is a digital cellular communications system that was initially introduced in the European market but, it has gained widespread acceptance throughout the world. It was designed to be compatible with ISDN systems and the services provided by GSM are a subset of the standard ISDN services (speech is the most basic).

The operational components of a GSM cellular system include mobile stations, base stations, and the network subsystem. The mobile stations are the small, hand-held telephones that are carried by subscribers. The base station controls the radio link with the mobile stations and the network subsystem performs the switching of calls between the mobile and other fixed or mobile network users.

The GSM transmission technology utilizes the Gaussian Minimum Shift Keying form of modulation (GMSK). In this modulation scheme, the phase of the carrier is instantaneously varied by the modulating signal. Important characteristics of GMSK modulation are that the output signal has a constant envelope, relatively narrow bandwidth and coherent detection capability. However, the most important of these characteristics is the constant envelope. Signals that have a constant envelope are more immune to noise than signals with varying amplitudes.

In addition, because GMSK modulation does not include amplitude components, the transmitter does not require the use of a linear power amplifier. Power amplifiers operating in the non-linear region typically deliver much higher efficiencies than when they are operating in the linear region. Cellular modulation technology that includes amplitude components, such as CDMA (IS-95), TDMA (IS-136) and EDGE, are highly dependent upon maintaining linearity of the power amplifier. Thus, mobile stations based on such technology typically utilize an isolator at the output of the power amplifier, or implement other methods to preserve linearity of the power amplifier. GMSK technology does not require an isolator which is a great benefit due to the size and cost of a typical isolator; however, the absence of such an isolator creates additional technological problems in a GSM system.

In GSM technology, the output of the power amplifier is typically fed into a harmonic filter, a transmit/receive switch and an antenna. It is not uncommon for a mismatch condition of as high as 10:1 Voltage Standing Wave Ration (VSWR) or worse to be present at the antenna—which has a very significant affect on the output load impedance seen by the power amplifier. Unfortunately, power amplifiers are typically designed to operate with a constant load impedance of 50 Ohms. Thus, the efficiency of operation for a power amplifier is degraded as the VSWR increases and the load impedance changes.

When a power amplifier is operating at an efficiency level that is lower than what it was designed for, an over current condition can be created. Such a condition can be catastrophic in that it puts unnecessary drain onto the battery and thus reduces the time required between battery charge cycles. In addition, as the efficiency of the power amplifier is decreased, the output spectrum can degrade and the spurious output level can exceed the levels required in the specifications for GSM technology. Thus, there is a need in the art for a system that prevents loop saturation in a power amplifier system, which results in a decrease in the efficiency of a power amplifier operating in a GSM system. Similarly, there is a need in the art to prevent such power amplifiers from drawing excessive amounts of current and degrading the output spectrum as a result of a decrease in efficiency.

Three techniques have been introduced to the market to address this need in the art; however, as is shown in this document, these techniques fall short of being a viable solution. FIG. 1 is a circuit diagram illustrating the most conventional method for controlling the out power of a power amplifier. This method utilizes a power coupler 101 and a detector 102. In operation, this circuit detects the output power of the power amplifier 103 and compares the detected voltage 104 with a reference voltage 105 by the use of an integrator 106 to generate an error voltage 107. The error voltage 107 is then applied to the power amplifier 103 to close the loop and adjust the output power of the power amplifier 103. This is a true closed loop system that tracks power very accurately. Because this system detects the power output of the power amplifier 103, the output power variation is less of a concern, however, the over current condition can affect the battery life and spectrum purity.

FIG. 2 is a circuit diagram illustrating a similar method as the one illustrated in FIG. 1 for controlling the output power of a power amplifier. In this method, the circuit detects the collector/drain current 201 being provided to the power amplifier 203 instead of detecting the output power directly. This is also a closed loop system but does not offer the level of accuracy seen in the power detector system of FIG. 1. This system is very effective at preventing the over current condition, but the output power variation control is not as accurate as the power detection method shown in FIG. 1.

FIG. 3 is a circuit diagram illustrating a quasi-closed loop system that utilizes a transistor in series with the collector (drain) supply for controlling the supply power provided to a power amplifier. The transistor 301 regulates the collector (drain) voltage to regulate the Vcc (Vdd) 302. This method can be highly accurate and stable as long as the battery voltage stays above a threshold and the output is presented with a 50 ohm load. Unfortunately, these ideal conditions are not guaranteed in handset applications. Both the output power and current variations can be quite high when a mismatch load is presented. Because of the voltage drop caused by the pass transistor 301, the battery threshold voltage is usually higher than that in the methods illustrated in FIGS. 1 and 2.

The techniques illustrated in FIGS. 1-3 are insufficient in addressing the issues associated with GSM using GMSK modulation. One of the reasons for this insufficiency is that the prior art systems expect to operate against a matched load of 50 ohms. In GSM products, such an ideal condition is not available and the load impedance can greatly fluctuate. The present invention provides a novel solution for GSM type transmitters.

### SUMMARY OF THE INVENTION

The present invention provides a solution to the deficiencies in the current art by providing a power control circuit that detects and limits the voltage and/or current being provided to a power amplifier. The present invention uses a pass transistor to control the voltage being provided to the power amplifier. In one embodiment of the present invention, the resistance characteristics of the pass transistor are determined. In operation, the voltage drop across the pass transistor is detected and divided by the expected resistance of the pass transistor to determine the current being provided to the power amplifier. If the current level exceeds a threshold level, a voltage applied to the base of the pass transistor through a voltage comparator is adjusted to limit the current. In another embodiment, this adjustment is made by simply comparing the supply voltage of a power source and the voltage level being provided to the power input of the power amplifier. The present invention can be implemented using discrete components or circuits or may be incorporated in a base band ASIC.

### BRIEF DESCRIPTION OF THE DRAWINGS

FIG. 1 is a circuit diagram illustrating the most conventional method for controlling the output power of a power amplifier.

FIG. 2 is a circuit diagram illustrating a similar method as the one illustrated in FIG. 1 for controlling the output power of a power amplifier.

FIG. 3 is a circuit diagram illustrating a quasi-closed loop system that utilizes a transistor in series with the collector (drain) supply for controlling power provided to a power amplifier.

FIG. 4 is a circuit diagram that can be incorporated into a radio frequency type transmitter to provide the power control of the present invention.

FIG. 5 is a circuit diagram that can be incorporated into a radio transmitter to provide the power control of the present invention.

FIG. 6 is a flow diagram illustrating the steps involved in one embodiment of the present invention.

FIG. 7 is a flow diagram illustrating the steps involved in another embodiment of the present invention.

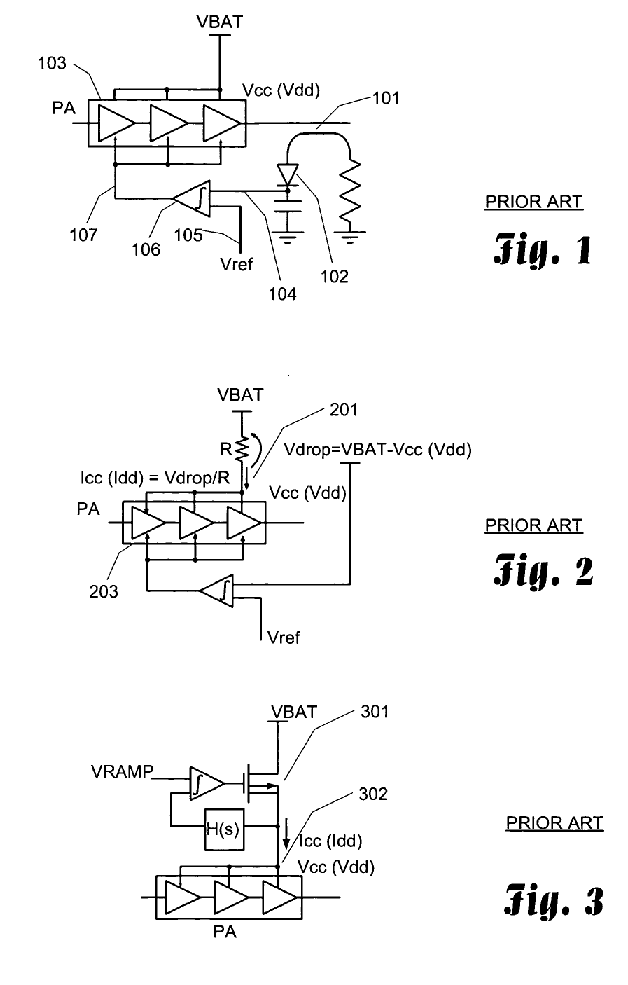

### DETAILED DESCRIPTION

The present invention provides a power control circuit that operates to prevent, or reduce the likelihood of an over current condition in the power amplifier circuitry. In general, the present invention detects the power being utilized by a power amplifier by either monitoring the current supplied to the power amplifier or by monitoring the level of the supply voltage. Typically, when an over current condition exists in the power amplifier, the frequency characteristics of the power amplifier are either approaching, or are actually out of specification requirements. For instance, in a cellular transmission system, the mobile stations are required to limit the output power and spurious emissions according to specifications for the cellular transmission system. These specifications are established to prevent cross-talk and channel interference within the cellular frequency spectrum, as well as reduce electromagnetic interference.

Turning now to the figures in which like numbers and labels refer to like elements, the present invention is described in greater detail.

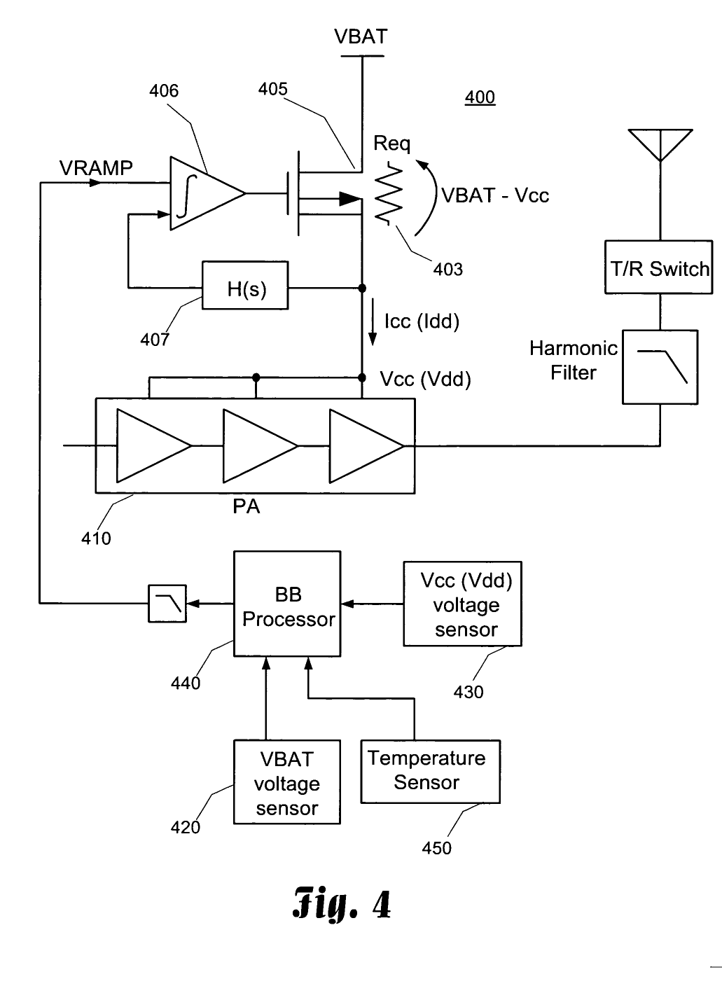

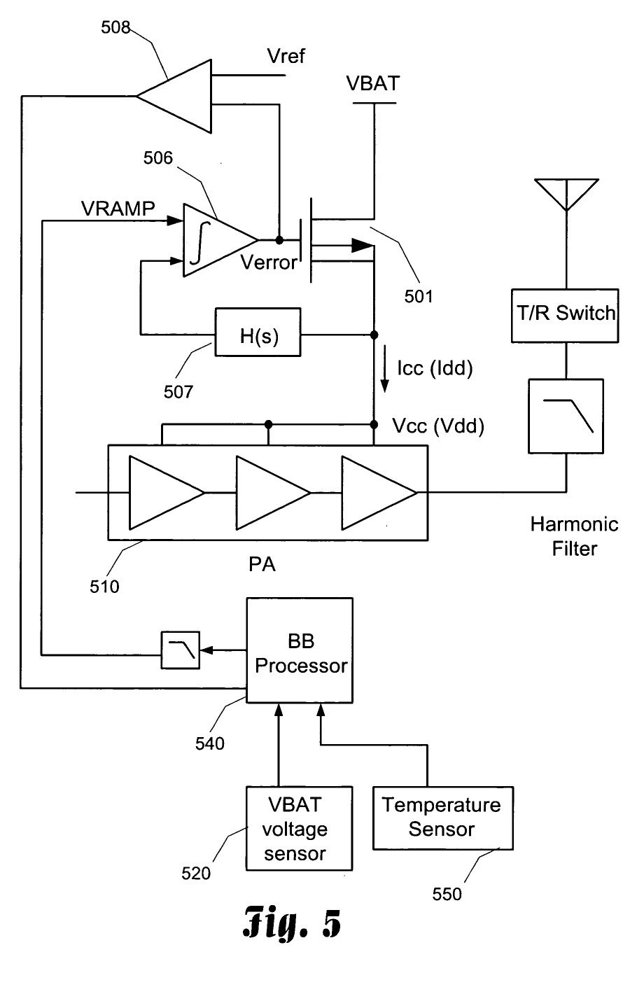

FIG. 4 is a circuit diagram that can be incorporated into a radio frequency type transmitter to provide the power control of the present invention. This embodiment of the invention monitors the Vcc (Vdd) voltage being supplied to the power amplifier. The power amplifier system 400 includes a voltage sensor 430 that senses the voltage level Vcc (Vdd) being provided to a power amplifier 410. In one embodiment, the Vcc (Vdd) voltage can be converted to a digital signal through an anolog-to-digital converter (not shown). The value of Vcc (Vdd) is provided to a processor 440.

A pass transistor 405 is used to provide the supply voltage Vcc (Vdd) to the power amplifier 410. The current being provided to the power amplifier 410 passes through the pass transistor 405 and is controlled by integrator 406 and a feedback circuit 407. The pass transistor 405 includes a resistance 403 in the path from the battery supply Vbat to the power amplifier 410 or across the source and drain nodes of the pass transistor 405. This resistance can be characterized and calibrated by measuring the pass transistor's resistance at various voltage levels. In one embodiment, a look-up table can be constructed to identify the resistance 403 of the pass transistor 405 during various voltage conditions. Although the pass transistor 405 is shown as a P channel FET, the selection of this component is only as an example and should not limit the present invention. For instance, a PNP bipolar junction transistor could also be used. In addition, the logical operation can be reversed simply by using an N channel FET or NPN bipolar junction transistor and the present invention can operate just as effectively. The look-up table can be stored in a memory that is included in the processor 440 or external to the processor 440. Other techniques may also be employed such as using the characteristics of the pass transistor resistance 403 to formulate an equation that can be used to calculate the resistance of the pass transistor under various conditions. The parameters that can be used to index a look-up table or serve as values in the equation can include, but are not limited to, the level of the battery voltage, the temperature of various components such as the power amplifier, the voltage level being supplied to the power amplifier and the current drained by the power amplifier.

Once the resistance 403 of the pass transistor 405 is determined, this information can be used to determine the current Icc (Idd) being provided to the power amplifier 410. For instance, the voltage drop across the pass transistor 405 can be determined by dividing the voltage drop across the pass transistor 405 (Vbat-Vcc) by the resistance 403 of the pass transistor 405 for the given operating conditions.

In operation, a voltage sensor 430 monitors the voltage level Vcc (Vdd) being provided to the power amplifier 410. The sensed voltage level Vcc (Vdd) is provided to the processor 440. A battery voltage sensor 420 monitors the voltage level being provided from a battery power source Vbat (not shown). The sensed Vbat voltage level is also provided to the processor 440. The processor uses the Vcc (Vdd) and Vbat voltage levels, along with the resistance 403 characterization information regarding the pass transistor 405 to determine the current drain Icc (Idd) of the power amplifier 410. Based at least in part on the Vcc (Vdd), Vbat and current drain information, the processor can adjust the output signal Vramp which is provided to one input terminal of the integrator 406. The other input terminal of the integrator 406 is electrically coupled to the source of the pass transistor 405 as a voltage feedback. As those skilled in the art will be familiar with, the pass transistor 405, in conjunction with the feedback control loop, operate to limit the voltage provided to the power amplifier 410. When the processor determines that the current drain Icc (Idd) of the power amplifier is too high, the processor adjusts the value of Vramp so that the current drain of the power amplifier 410 will be further limited. Likewise, the processor can also determine that the current drain Icc (Idd) of the power amplifier is below a desired threshold level. When this condition occurs, the processor can adjust the value of Vramp so that the current drain of the power amplifier 410 will be increased.

Thus, this embodiment of the present invention operates to detect over current conditions in the power amplifier that could result in violation of transmission specifications, and rectifies the problem by limiting the current drain.

In another embodiment of the invention, an over current situation can be detected simply by comparing the value of Vcc (Vdd) to the voltage level of the battery Vbat. In this embodiment, when the Vcc decreases too much relative to the battery voltage level, it is an indication that the power amplifier 410 is drawing too much current. In addition, threshold values for the battery voltage can be used to determine if this is actually an over current condition or if the battery voltage is simply dropping due to a loss of charge. If an over current condition is detected, the processor can operate to lower the ramp voltage Vramp provided to voltage comparator 406 to prevent the over current condition.

In either of these embodiments, measuring the current into the power amplifier 410 or comparing the level of Vcc to the battery voltage Vbat, the present invention operates to determine whether the power amplifier 410 is approaching saturation. If the power amplifier is approaching saturation, the level of the ramp voltage Vramp can be reduced to prevent saturation.

In another embodiment, a temperature sensor 430 may be used to detect the temperature of one or more components such as the power amplifier 410, the pass transistor 405 and/or the integrator 406. Based on the value of the temperature level, the processor can further adjust the value of the Vramp signal.

One advantage of this technique for controlling the power supplied to the power amplifier 410 is that no additional components are required to implement the system. In addition, the requirement of an isolator at the output of the power amplifier 410 is eliminated.

FIG. 5 is a circuit diagram that can be incorporated into a radio transmitter to provide the power control of the present invention. This embodiment of the invention monitors an error voltage that is used to monitor and control the supply voltage Vcc (Vdd) being provided to a power amplifier 510. The power amplifier 510 is powered by a battery through a pass transistor 501. The supply voltage Vcc (Vdd) to the power amplifier 510 is controlled by a voltage controller consisting of the pass transistor 501, the feedback circuit 507 and integrator 506. The integrator 506 receives a ramp voltage input Vramp from the processor 540 and the feedback signal from the feedback circuit 507.

When the power amplifier draws too much current, or when the battery voltage drops too low, the voltage control loop can go into saturation. This occurs because the battery voltage is not high enough to account for the voltage drop of the pass transistor 501 while providing the voltage required at Vcc (Vdd). When the voltage control loop approaches saturation, there is a decrease in the output error signal of the integrator 506 (Verror). Eventually, this condition will result in the Verror level hitting the voltage rail of the integrator 506.

To prevent the voltage control loop from entering saturation, the error voltage (Verror) from the integrator 506 is compared to a reference voltage (Vref) by voltage comparator 508. By setting Vref just above (or below depending on the topology used) the threshold to detect loop saturation, the ramp voltage (Vramp) signal can be adjusted until the voltage control loop in no longer in saturation.

In an exemplary embodiment, a processor is used to set the reference voltage Vref and the ramp voltage Vramp. Thus, as the error voltage Verror approaches the rail, the reference voltage Vref is used to detect this condition and signal the processor to decrease the value of the ramp voltage Vramp. In an alternate embodiment, the processor can also detect when the error voltage Verror is below the rail, and adjust the Vramp level to a higher value until it is detected that the Verror signal is at the rail.

This embodiment of the invention can also incorporate a voltage sensor 520 for detecting the voltage level of a power source, such as a battery Vbat. Based on the value of the power source Vbat, the processor can further adjust the value of the ramp voltage Vramp to account for low or high voltage levels. For instance, while a fully charged battery discharges, the voltage level provided by the battery slowly decreases. Typically the battery will have a knee voltage at which the output voltage level begins declining rapidly. This embodiment of the invention can detect when the discharge cycle of the battery is crossing or has crossed the knee voltage. When the battery is in the portion of the discharge cycle, the present invention can refrain from adjusting the value of Vramp because the loop saturation is most likely due to the discharge of the battery.

In another embodiment, a temperature sensor 550 may be used to detect the temperature of one or more components such as the power amplifier 510, the pass transistor 501 and/or the voltage comparators 506 and 508. Based on the value of the temperature level, the processor can further adjust the value of the Vramp signal. For instance, the resistance 403 of the pass transistor 405 can significantly change over the operating temperature range of the circuit. In addition, the responsiveness of the loop-back circuit can vary over temperature. Thus, in this embodiment of the present invention, such variations can be accounted for and thus, the adjustments to Vramp can be more accurately controlled.

The present invention can be used in a variety of configurations and the circuits provided in FIGS. 4 and 5 are just two examples of such implementations. The present invention can be incorporated in to the circuit illustrated in FIG. 3 as well as other circuits.

In one embodiment, the present invention can be incorporated into a mobile telephone handset but, those skilled in the art will realize that the present invention is equally applicable for any transmission technology, even transmission technology that uses amplitude based modulation schemes.

The present invention is most applicable at higher power levels. Cellular systems typically have a range of power levels at which the mobile stations can transmit. At the higher power levels, the power amplifier is more prone to saturation. Thus, the present invention is particularly applicable to operation at the higher power levels.

In implementing the present invention, a preferred embodiment is to incorporate the processor and the analog to digital conversions onto a single chip, typically referred to in the industry as the base band processor. However, the present invention can be implemented using discrete components, a combination of ASICs or other integrated circuits, as well as a combination of hardware and software/firmware components.

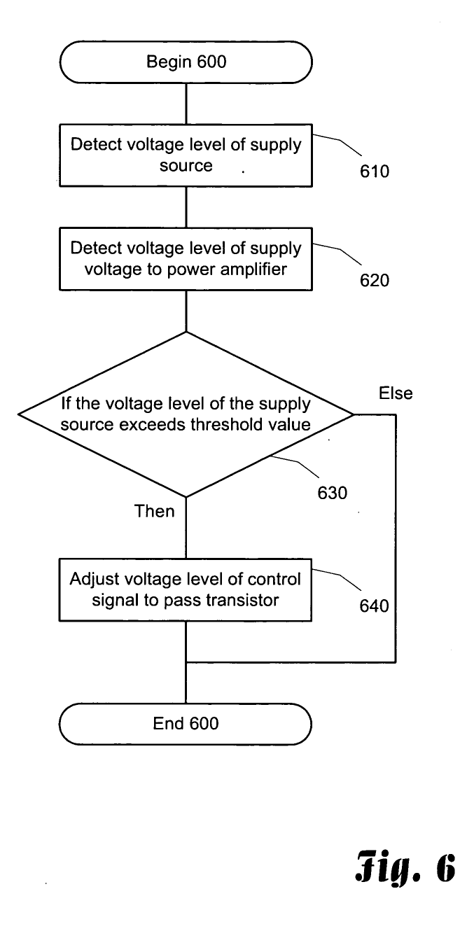

FIG. 6 is a flow diagram illustrating the steps involved in one embodiment of the present invention. In this embodiment, the voltage level of the supply source is detected at step 610. At step 620, the voltage level of the supply voltage to the power amplifier is detected. At step 630, the voltage level of the supply source is compared to a threshold value. If the threshold value is exceeded, then at step 640, the voltage level of a control signal, for instance the control signal to the voltage comparator 406 in FIG. 4, is adjusted. Otherwise processing is ended.

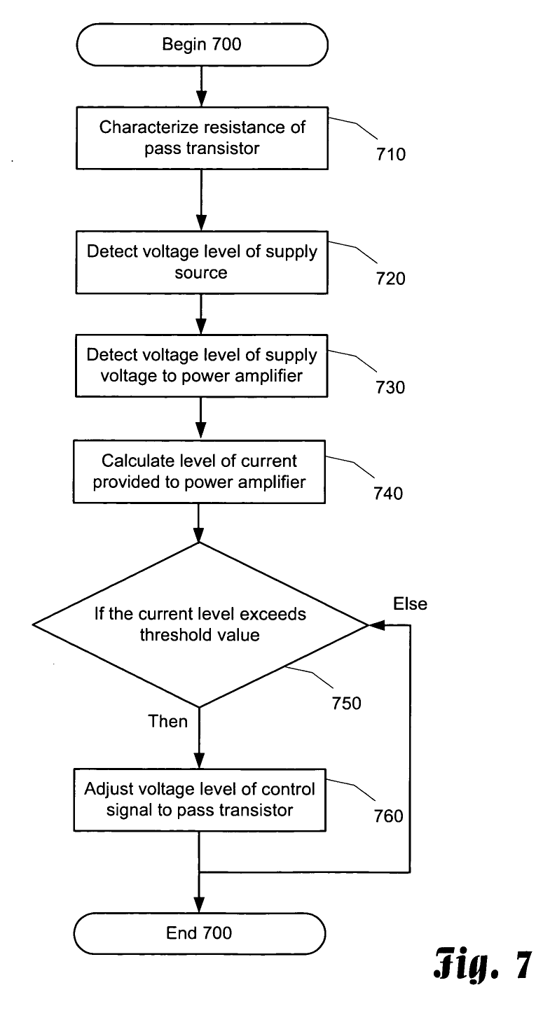

FIG. 7 is a flow diagram illustrating the steps involved in another embodiment of the present invention. In this embodiment, the resistance characteristics of a pass transistor, such as pass transistor 405 in FIG. 4, is determined at step 710. At step 720, the voltage level of the supply source is detected. At step 730, the voltage level of the supply voltage to the power amplifier is detected. At step 740, the level of the current being provided to the power amplifier is determined. This can be determined by dividing the difference in the supply voltage and the voltage level being provided to the power amplifier by the resistance of the pass transistor. At step 750, the current level being provided to the power amplifier is compared to a threshold value. If the current exceeds this threshold value, the voltage level of control signal, for instance the control signal to the voltage comparator 406 in FIG. 4, can be adjusted. If the current does not exceed the threshold, processing is ended.

It should be understood that the ordering of the steps illustrated in FIGS. 6 and 7 are for purposes of example and should not limitation. It is also anticipated that the present invention can be described as operating in a looping manner in which the comparison is continually performed and the Vramp level constantly adjusted.

The present invention has been described using detailed descriptions of embodiments thereof that are provided by way of example and are not intended to limit the scope of the invention. The described embodiments comprise different features, not all of which are required in all embodiments of the invention. Some embodiments of the present invention utilize only some of the features or possible combinations of the features. Variations of embodiments of the present invention that are described and embodiments of the present invention comprising different combinations of features noted in the described embodiments will occur to persons of the art. The scope of the invention is limited only by the following claims.

1. A method of controlling supply power provided to a power amplifier to prevent loop saturation, the method comprising the steps of:
detecting the voltage level of a supply source;
detecting the voltage level of a supply voltage to the power amplifier provided from the supply source through a pass transistor, the pass transistor having a control input;
comparing the voltage level of the supply source to a first threshold value;
if the voltage level of the supply source is above the first threshold value, comparing the voltage level of the supply voltage to the power amplifier to the voltage level of the supply source; and
based on the comparison of the voltage level of the supply to the power amplifier and the voltage level of the supply source, adjust a voltage level of a control signal provided to the control input of the pass transistor.

2. The method of claim 1, further comprising the step of detecting a temperature level of the power amplifier and the step of adjusting the voltage level of the control signal further comprises adjusting the voltage level based on the temperature level of the power amplifier.

3. A method of controlling power provided to a power amplifier to prevent loop saturation, the method comprising the steps of:
characterizing the resistance of a pass transistor over a voltage range, the pass transistor providing an electrical path from a power source to a supply power input of the power amplifier and a control input;
detecting the voltage level of the power source;
detecting the voltage level of the supply power input of the power amplifier;
calculating the level of current being provided to the power amplifier based on the voltage level of the supply power source, the voltage level of the supply power input to the power amplifier and the characteristics of the resistance of the pass transistor;
if the level of current being provided to the power amplifier exceeds a threshold value, adjusting the voltage level provided to the control input of the pass transistor, whereby the current provided to the power amplifier is decreased.

4. The method of claim 3, further comprising the step of detecting a temperature level of the power amplifier and the step of adjusting the voltage level of the control signal further comprises adjusting the voltage level based on the temperature level of the power amplifier.

5. The method of claim 4, wherein the step of characterizing the resistance of the pass transistor further comprises creating a look-up table that associates various voltages and temperature levels with various resistances.

6. The method of claim 3, wherein the step of characterizing the resistance of the pass transistor further comprises creating a look-up table that associates various voltages with various resistances.

7. A circuit for controlling the power provided to a power amplifier to prevent loop saturation, the circuit comprising:
a pass transistor, a voltage comparator, and a processor,
the pass transistor having a output, an input and a control input, the input being coupled to a supply power source, the output being coupled to the supply power input of the power amplifier and the control input receiving a first comparison signal from the integrator;
the integrator having a control voltage input, a feed back input and a comparison output, the control voltage input being coupled to a first control output from the processor, the feed back input being coupled to the output of the pass transistor through a feed back circuit and the comparison output being coupled to the control input of the pass transistor;
the processor having a first voltage sensor coupled to the supply power source, a second voltage sensor coupled to the supply power input of the power amplifier and a control voltage output coupled to the voltage control input of the integrator, the processor being operative to control the supply power to the power amplifier by:
comparing the voltage level of the supply power source and the voltage level of the supply power input to the power amplifier; and
adjusting the voltage control output based at least in part on the results of this comparison.

8. The circuit of claim 7, wherein the processor is further operative to determine the resistance of the pass transistor and the step of adjusting the voltage control output is further based on the value of the resistance.

9. The circuit of claim 8, wherein the processor is operative to determine the resistance of the pass transistor by performing a lookup function in a table stored in a memory accessible to the processor that includes a correlation of resistant values with voltage levels.

10. The circuit of claim 8, wherein the processor is operative to calculate the resistance of the pass transistor based at least in part on the value of the voltage level of the supply power source.

11. The circuit of claim 8, wherein the processor is operative to calculate the resistance of the pass transistor based at least in part on the value of the supply voltage level being provided to the power amplifier.

12. The circuit of claim 8, wherein the processor is operative to calculate the resistance of the pass transistor based at least in part on the voltage level of the supply power source and the supply voltage level being provided to the power amplifier.

13. The circuit of claim 8, wherein the processor is operative to determine the value of the current being provided to the power amplifier by dividing the difference in the voltage level of the supply power source and the supply voltage level being provided to the power amplifier by the resistance and the step of adjusting the voltage control output is based on the value of the current.

14. The circuit of claim 13, wherein the voltage control output is adjusted if the value of the current exceeds a threshold value.

15. The circuit of claim 14, further comprising a temperature sensor with a temperature value output that is coupled to a temperature input of the processor, and the processor is operative to adjust the voltage control output further based on the value of the temperature sensor input.

16. A circuit for controlling the supply power provided to a power amplifier to prevent loop saturation, the apparatus comprising:
a pass transistor having an input, an output and a control input, the input being coupled to a supply power source, the output being coupled to the supply power input of the power amplifier and the control input receiving a first control signal from a first integrator;
the first integrator have a first control voltage input, a feed back input and a first comparison output, the first control voltage input being coupled to a first control output from a processor, the feed back input being coupled to the output of the pass transistor through a feed back circuit and the first comparison output being coupled to the input control of the pass transistor;
a second integrator having a second control voltage input, a third control voltage input and an second comparison output, the second control voltage input being coupled to a second control output from the processor, the third control input being coupled to the first comparison output of the first integrator and the second comparison output being coupled to a comparison input of the processor; and
the processor being operative to control the voltage level being provided to the power amplifier through the pass transistor by adjusting the level of the first control output and the second control output based at least in part on the level of the comparison input.

17. The circuit of claim 16, further comprising a temperature sensor with a temperature value output that is coupled to a temperature input of the processor, and the processor is operative to adjust the voltage level being provided to the power amplifier through the pass transistor further based on the value of the temperature sensor input.

18. A mobile station for use in a cellular system, the mobile station comprising:
a power amplifier having a power input, a pass transistor, a integrator, and a processor,
the pass transistor having an output, an input and a control input, the input being coupled to a supply power source, the output being coupled to the supply power input of the power amplifier and the control input receiving a first comparison signal from the integrator;
the integrator having a control voltage input, a feed back input and a comparison output, the control voltage input being coupled to a first control output from the processor, the feed back input being coupled to the output of the pass transistor through a feed back circuit and the comparison output being coupled to the control input of the pass transistor;
the processor having a first voltage sensor coupled to the power source, a second voltage sensor coupled to the power input of the power amplifier and a control voltage output coupled to the voltage control input of the voltage comparator, the processor being operative to control the supply power to the power amplifier by:
comparing the voltage level of the supply power source and the voltage level of the supply power input to the power amplifier; and
adjusting the voltage control output based at least in part on the results of this comparison.
